(19) United States
(12) Patent Application Publication
(10) Pub. No.: US 2025/0040092 A1
(43) Pub. Date: Jan. 30, 2025

(54) Scanning system comprising a channel system for a coolant

(71) Applicant: SCANLAB GMBH, Puchheim (DE)

(72) Inventor: David Schatz, Muenchen (DE)

(21) Appl. No.: 18/696,618

(22) PCT Filed: Sep. 29, 2022
(86) PCT No.: PCT/EP2022/077135

§ 371 Date: Mar. 28, 2024

(30) Foreign Application Priority Data
Sep. 29, 2021 (DE) 10 2021 125 281.4

(51) Int. Cl. H05K 7/20; G02B 26/10

(52) U.S. Cl. CPC H05K 7/20327; G02B 26/10

(57) ABSTRACT

In one aspect, a scan system for guiding a laser beam includes a housing body having at least one housing channel intended for distributing a coolant. The scan system also includes at least one cooling body, which is arranged in a housing interior of the housing body and has a receiving recess for a deflection unit. The at least one cooling body also has at least one cooling channel that is connected to the housing channel, is intended for cooling the deflection unit, and is formed in the cooling body. The housing channel and the cooling channel are each formed by at least one bore. Furthermore, the housing body and the cooling body have corresponding contact surfaces in which the housing body and the cooling body abut one another such that a channel opening of the housing channel and a channel opening of the cooling channel overlap one another.

### CROSS-REFERENCE TO RELATED APPLICATIONS

The present application is a U.S. national phase entry of International Patent Application No. PCT/EP2022/077135, filed Sep. 29, 2022, which, in turn, is based upon and claims the right of priority to German Patent Application No. 10 2021 124 281.4, filed Sep. 29, 2021, the disclosures of which are hereby incorporated by reference herein in their entirety for all purposes.

### FIELD OF THE INVENTION

The present subject matter relates to a scan system for guiding a laser beam, the scan system having a housing body, which delimits or defines a housing interior and includes at least one housing channel, which is intended for distributing a coolant and is formed in the housing body. The scan system also includes at least one cooling body, which is arranged in the housing interior, is detachably connected to the housing body, has a receiving recess for a deflection unit, and has at least one cooling channel, which is connected to the housing channel, is intended for cooling the deflection unit, is formed in the cooling body and is arranged adjacent to the receiving recess. The present subject matter further relates to a housing body, which is designed for use in a scan system of this type, and to a cooling body.

### BACKGROUND OF THE INVENTION

DE 10 2013 003 939 A1 describes a laser beam deflection device for an apparatus for constructing three-dimensional objects. The laser beam deflection device includes at least one deflection mirror, a motor for controlling the deflection mirror and a housing, which accommodates at least the deflection mirror, wherein the housing and peripheral housing parts arranged on the housing are formed by a powder material which is solidified in an additive process by complete or partial melting, at least in some areas (in particular in the bearing region of the at least one deflection mirror and in the region of beam-guiding optical components). It is disadvantageous that such additive manufacturing methods are highly complex and expensive.

Accordingly, there is a need for a scan system that eliminates one or more of the disadvantages known on the from prior art. For example, there is a need to provide a scan system, which includes cooling, has small overall dimensions and can be cost-effectively manufactured and/or assembled with little effort.

### SUMMARY OF THE INVENTION

In various aspects, the present subject matter is directed to a scan system for guiding a laser beam, a housing body provided therefor, and cooling bodies having the features described and claimed herein.

In one aspect, the present subject matter relates to a scan system for guiding a laser beam. The scan system is preferably intended for a laser for material machining and/or for detecting a measured value. The scan system is, in particular, a laser machining scanner and/or a sensor scanner. In particular, the scan system is intended for a laser machining device. The scan system includes a housing body which delimits or defines a housing interior and has at least one housing channel for distributing a coolant. This housing channel is formed in the housing body. As a result, the housing channel preferably extends through the material of the housing body and/or is encased by this material of the housing body. Furthermore, the scan system includes at least one cooling body, which is arranged in the housing interior and is detachably connected to the housing body. The cooling body has a receiving recess for a deflection unit. In this receiving recess, the corresponding deflection unit can be detachably mounted in the cooling body. Furthermore, the cooling body includes at least one cooling channel for cooling the deflection unit, the cooling channel being connected to the housing channel. The cooling channel is formed in the cooling body. As a result, the cooling channel preferably extends through the material of the cooling body and/or is encased by the material of the cooling body. Furthermore, the cooling channel is preferably adjacent to the receiving recess. The housing channel is formed at least by at least one bore in the housing body. The housing body therefore has at least one bore, which at least partially forms the housing channel. Furthermore, the cooling channel is formed by at least one bore in the cooling body. The cooling body therefore has at least one bore, which at least partially forms the cooling channel. Advantageously, the housing channel and the cooling channel can therefore be very quickly and cost-effectively manufactured. Furthermore, the housing body and the cooling body have corresponding contact surfaces. The housing body and the cooling body abut one another, in particular directly, in these contact surfaces such that a channel opening of the housing channel, which is formed in the contact surface of the housing body, and a channel opening of the cooling channel, which is formed in the contact surface of the cooling body, at least partially overlap. The coolant can therefore flow directly between the housing body, specifically its housing channel, and the cooling body, specifically its cooling channel. Advantageously, as a result, additional connecting elements such as, for example, tubes, can be eliminated, thereby reducing the installation effort and the manufacturing costs of the scan system. Furthermore, the overall dimensions of the scan system can be reduced due to the direct connection of the housing channel to the cooling channel. The risk of leaks is also reduced since the housing channel transitions directly into the cooling channel and, as a result, the channel section formed thereby is formed exclusively of solid material of the housing body and of the cooling body.

In order to ensure simple manufacture and/or assembly, it is advantageous when the housing body is of a multi-part design. Therefore, it is advantageous when the housing body has a first part, on which preferably the at least one cooling body and/or an aperture body are/is detachably mounted. Furthermore, it is advantageous when the housing body includes a second part in which an electronic-component heat sink is detachably mounted.

In order to be able to exchange the coolant between the two parts, it is advantageous when the two parts have corresponding contact surfaces and corresponding channel openings. In this regard, it is advantageous when the two parts abut one another, in particular directly, in their corresponding contact surfaces such that a channel opening of a first housing channel, which is formed in the contact surface of the first part, and a channel opening of a second housing channel, which is formed in the contact surface of the second part, overlap.

It is advantageous when the bore has a constant diameter across its entire length. As a result, flow resistance can be reduced. Furthermore, the bore can therefore be manufactured very easily and with little effort.

In order to be able to rule out a leak in the region of the two corresponding and/or directly abutting contact surfaces of the housing body and of the cooling body, it is advantageous when a sealing element is arranged between the two corresponding and/or abutting contact surfaces. The sealing element is preferably designed such that it surrounds the channel openings in the circumferential direction. The sealing element can be, for example, an O-ring. In order to ensure that the sealing element does not slip, it is advantageous, furthermore, when a groove is formed in at least one of the two contact surfaces, with the sealing element being arranged in the groove.

It is advantageous when the housing channel and/or the cooling channel each have at least one inlet channel opening for introducing the coolant and at least one outlet channel opening for discharging the coolant.

Manufacturing complexity is increased when the housing channel and/or the cooling channel have/has further production-related openings in addition to the at least one inlet channel opening and the at least one outlet channel opening, respectively, which production-related openings must be retroactively sealed. For this reason, it is advantageous when the housing channel and/or the cooling channel each have exclusively at least one inlet channel opening and at least one outlet channel opening. In this case, the housing channel and/or the cooling channel include(s) only at least one inlet channel opening and only at least one outlet channel opening.

In this context, it is advantageous, furthermore, when the cooling channel of the cooling body has only one single inlet channel opening and only one single outlet channel opening. The cooling channel therefore does not have any production-related, additional openings. Accordingly, the manufacturing complexity can be advantageously reduced.

Highly cost-effective and fast manufacturing of the housing channel and/or of the cooling channel can be ensured when the housing channel and/or the cooling channel are/is formed as at least one through-hole. As a result, the at least one through-hole has the inlet channel opening at its one end and the outlet channel opening at its other end.

It is also advantageous for cost-effectively and quickly manufacturing the housing channel and/or the cooling channel when the housing channel and/or the cooling channel are/is formed by at least one blind bore. The housing channel and/or the cooling channel can therefore be composed, for example, of at least one through-hole and at least one blind bore.

It is also advantageous when the housing channel and/or the cooling channel are/is formed, in particular, by multiple and/or at least two blind bores, which are oblique with respect to one another and intersect one another. The blind bores preferably intersect in the region of their housing-internal ends.

In this context, it is advantageous when the blind bores form an acute, right or obtuse angle with one another. Advantageously, the cooling liquid can therefore be conducted via simple channel geometries to different points of the housing body and/or of the cooling body.

It is advantageous when the housing channel and/or the cooling channel are/is formed by only or exclusively two blind bores, which are oblique with respect to one another. In this context, it is advantageous, furthermore, when the cooling body has a V-shaped cooling channel and/or the housing body has an L-shaped cooling channel.

In an advantageous enhanced embodiment of the present subject matter, the inlet channel opening and the outlet channel opening of the cooling channel are formed on the cooling body in the same contact surface of the cooling body and/or on the same side of the cooling body. Therefore, the cooling body preferably has a cooling-body side, which is intended to abut the housing body. The contact surface of the cooling body corresponding to the housing body is formed on this side of the cooling body. Furthermore, preferably the at least one inlet channel opening and the at least one outlet channel opening of the cooling channel are arranged in this contact surface. When the cooling body is mounted on the housing body, all channel openings are therefore aligned with one another and can be tightly press fit with the housing body.

It is also advantageous when the inlet channel opening and the outlet channel opening of the housing channel are formed on the housing body in different contact surfaces of the housing body and/or on different housing-body sides of the housing body. Advantageously, the coolant, in particular water, can therefore be introduced into the housing body on one side of the housing body and discharged therefrom on another side.

It is advantageous when the contact surface of the housing body, in particular of the first and/or the second part(s), and/or of the at least one cooling body is planar and/or curved, in particular concavely or convexly curved.

Additionally or alternatively, it is advantageous when the contact surface of the housing body, in particular of the first and/or the second part(s), and/or of the at least one cooling body is composed of multiple planar and/or, in particular concavely or convexly curved surface regions. The surface regions can form an angle with one another, preferably of less than 180°. It is advantageous when the inlet channel opening is formed in a first surface region and the outlet channel opening is formed in a second surface region.

It is advantageous when the corresponding contact surfaces, in particular of the housing body and of the at least one cooling body and/or of the two parts of the housing body, interlockingly engage into one another.

It is advantageous when the deflection unit is uniformly cooled from two sides. For this purpose, it is advantageous when the cooling body has a first cooling channel and a second cooling channel, which is separate from the first cooling channel. Preferably, the two cooling channels are formed on two opposite sides of the receiving recess. Furthermore, the two cooling channels are preferably formed and/or arranged symmetrically to one another.

It is advantageous when the first cooling channel and the second cooling channel of the cooling body are identical to one another. Additionally or alternatively, it is advantageous when the two cooling channels of the cooling body are arranged in parallel and/or symmetrically to one another. Furthermore, it is advantageous when the two cooling channels of the cooling body have a common plane of symmetry and/or when this common plane of symmetry of the two cooling channels extends centrally through the receiving recess.

It is also advantageous when the scan system has at least one cooling chamber for cooling an electronic component and/or for cooling an aperture. Preferably, the cooling chamber is formed at least partially in the housing body. As a result, at least some of the walls delimiting the cooling chamber are formed by the material of the housing body.

Cost-effective manufacturing of the cooling chamber can be ensured when the cooling chamber is die cut into the housing body. In this case, the cooling chamber has a manufacturing opening. Preferably, this manufacturing opening is formed on an inner face of the housing body, which faces the housing interior, or on an outer face of the housing body, which faces away from the housing interior.

It is advantageous when the housing body has a first cooling chamber for cooling the aperture, the cooling chamber preferably having a first manufacturing opening on the outer face of the housing, the first manufacturing opening being tightly closed by the aperture body, which is detachably connected to the housing body.

It is also advantageous when the housing body has a second cooling chamber for cooling the electronic component, the second cooling chamber preferably having a second manufacturing opening on the inner face of the housing, the second manufacturing opening being tightly closed by the electronic-component heat sink, which is connected to the housing body.

In an advantageous enhanced embodiment, the housing body has an inlet and an outlet for the cooling medium, the inlet and the outlet being preferably arranged and/or formed on the same side of the housing body.

It is advantageous when the housing body and/or the at least one cooling body are/is formed as a milled and/or drilled part and/or has been milled from a blank block. It is also advantageous when the milled part is provided with bores for forming the at least one housing channel and/or cooling channel during or after the milling operation, such that this is formed as a milled/drilled part.

In order to be able to ensure adequate cooling, it is advantageous when the scan system includes a channel system, which extends from the inlet to the outlet and is formed by the at least one housing channel, the at least one cooling channel and/or the at least one cooling chamber.

It is advantageous when the channel system has, in the direction of flow, a first channel section, which conducts an inlet flow of the coolant through the housing body.

It is advantageous when the channel system has, in the direction of flow, a second channel section, which divides the inlet flow into two cooling flows and conducts these cooling flows, separate from one another and/or connected in parallel to one another, through the housing body and/or the cooling body. In the at least one cooling body, the first cooling flow is preferably conducted through the first cooling channel and the second cooling flow is conducted through the second cooling channel of the cooling body.

Additionally or alternatively, it is advantageous when the channel system has, in the direction of flow, a third channel section, which combines the two cooling flows, in particular in the first cooling chamber, to form one common cooling flow, and conducts the common cooling flow through the housing body, in particular through the first cooling chamber for cooling the aperture and/or through the second cooling chamber for cooling the electronic component.

In another aspect, the present subject matter invention relates to a housing body or a cooling body which is designed for use in a scan system according to the preceding description, wherein the aforementioned features can be present individually or in any combination.

### BRIEF DESCRIPTION OF THE FIGURES

Further advantages of the invention are described in the following exemplary embodiment, wherein:

FIG. 1 shows a simplified schematic sectional view of a scan system which has a channel system for dividing a coolant, and

FIG. 2 shows a detailed view of the scan system shown in FIG. 1 in the region of a cooling body of a deflection unit.

### DETAILED DESCRIPTION

In the following description of the figures, the same reference characters are used for features that are identical and/or at least comparable in each of the various figures. The individual features, their embodiment and/or mode of operation are explained in detail usually only upon the first mention thereof. If individual features are not explained in detail once more, their embodiment and/or mode of operation correspond(s) to the embodiment and mode of operation of the features described above.

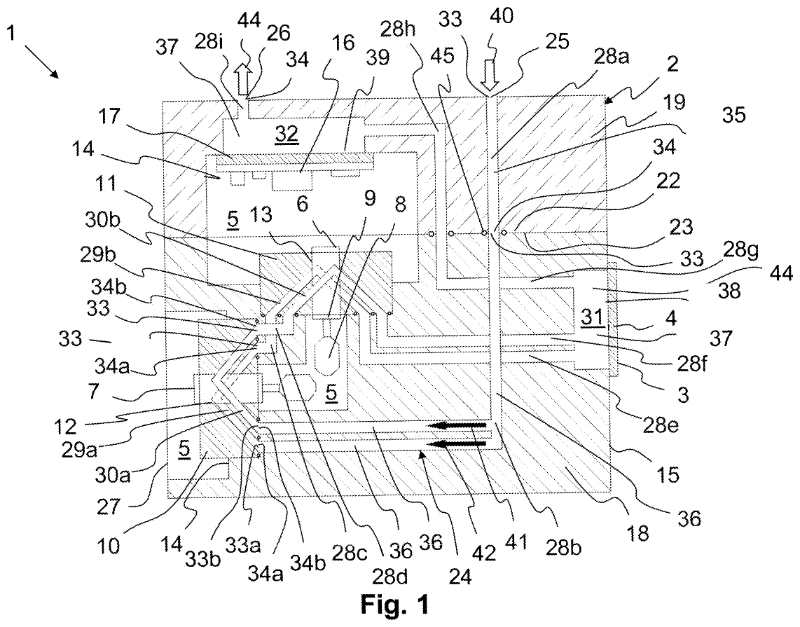

FIG. 1 shows a highly simplified, schematic sectional view of a scan system 1, with which a laser beam (not shown here) can be guided over an object surface. The scan system 1 can be, in particular, a laser machining scanner and/or a sensor scanner. Scan systems 1 of this type are used, for example, in laser machining devices.

The scan system 1 shown in FIG. 1 has a housing body 2 which accommodates multiple components of the scan system 1. An aperture body 3 is arranged on the housing body 2, in particular on an outer face 15 of the housing body 2, with the aperture body 3 having an aperture 4 through which the laser beam is introduced into a housing interior 5 of the housing body 2. Alternatively, the aperture body 3 can also be arranged in a recess, which is formed in the outer face 15, and, therefore, in the housing interior 5. The housing interior 5 is delimited or defined by an inner face 14 of the housing body 2. The housing interior 5 can be formed as an interconnected interior space. Alternatively, the housing interior 5 can also be composed of multiple interior spaces which are separate from one another. Furthermore, the housing interior 5 can have at least one opening toward the outer face 15 of the housing body 2. Preferably, the housing body 2 has a first opening, via which the laser beam can be introduced into the housing interior 5. This first opening is formed, in particular, by the aperture 4. Furthermore, the housing body 2 has at least one second opening, via which the laser beam can be guided out of the housing interior 5. Neither opening is shown in the schematic view of the scan system 1 shown in FIG. 1.

As shown in FIG. 1, the aperture body 3 is detachably mounted on the outer face 15 of the housing body 2. The laser beam is guided via the aperture 4 of the aperture body 3 to at least one deflection unit 6, 7. The deflection unit 6, 7 is arranged in the housing interior 5 in a protected manner. The deflection unit 6, 7 includes a deflection element 8, in particular a deflection mirror, which is mounted rotatably about an axis of rotation, and a drive 9, in particular a galvanometer motor, with which the deflection element 8 can be rotated, in particular about its longitudinal axis. For the sake of clarity, only one of the two deflection units 6, 7 is provided with these reference characters in FIG. 1.

The scan system 1 has at least one cooling body 10, 11 for cooling the deflection unit 6, 7. The cooling body 10, 11 is preferably formed in one piece. A receiving recess 12, 13 is formed in the cooling body 10, 11 within which the deflection unit 6, 7 can be accommodated. The deflection unit 6, 7 can be detachably mounted in the receiving recess 12, 13 of the cooling body 10, 11. Furthermore, the cooling body 10, 11 is detachably connected to the housing body 2. As a result, the deflection unit 6, 7 is indirectly mounted on the housing body 2 via the cooling body 10, 11.

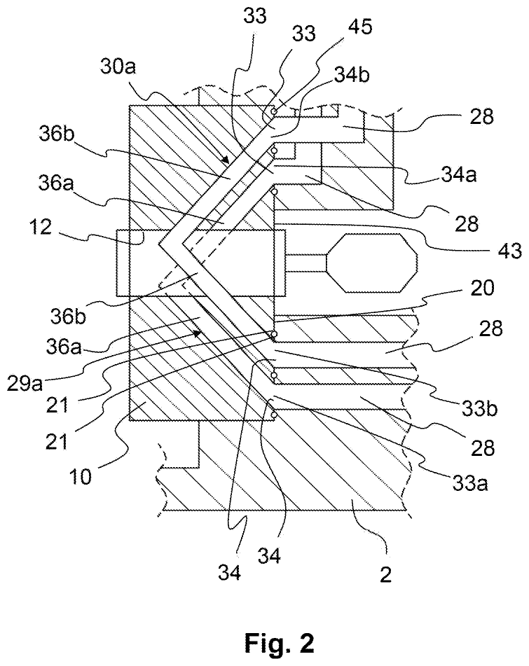

The cooling body 10, 11 and the housing body 2 have corresponding contact surfaces 20, 21 (FIG. 2) in which the cooling body 10, 11 and the housing body 2 abut one another preferably in a flush manner and/or directly. The contact surface 20 of the cooling body 10, 11 is formed on a side of the cooling body 10, 11 facing the deflection element 8 and/or is arranged adjacent to the receiving recess 12, 13.

The detachable connection between the cooling body 10, 11 and the housing body 2 is preferably established via screws (not shown here). Furthermore, the cooling body 10, 11 and the housing body 2 are connected to one another via alignment pins (also not shown here) in order to ensure that the cooling body 10, 11 is precisely positioned in the housing body 2. The alignment pins are preferably aligned parallel to the axis of rotation of the deflection element 8.

In the present exemplary embodiment, the scan system 1 includes a first deflection unit 6 and a second deflection unit 7 which is installed downstream in the propagation direction of the laser beam. The scan system 1 has a cooling body 10, 11 for each of the deflection units 6, 7, respectively, which cooling body 10, 11 is designed according to the preceding description.

The scan system 1 also includes at least one electronic component 16, which is arranged in the housing interior 5. The electronic component 16 can be, for example, a populated circuit board. The scan system 1 also includes an electronic-component heat sink 17 for cooling the electronic component 16. The electronic-component heat sink 17 is detachably mounted on the inner face 14 of the housing body 2, in particular via screws. The electronic component 16 is arranged on the side of the electronic-component heat sink 17 facing away from the inner face 14. As a result, the electronic component 16 is indirectly connected to the housing body 2 via the electronic-component heat sink 17.

According to FIG. 1, the housing body 2 is of a multi-part design. The housing body 2 has a first part 18 and a second part 19. The two parts 18, 19 also have corresponding contact surfaces 22, 23 at which the two parts 18, 19 abut one another in a flush manner and/or directly. The first cooling body 10, the second cooling body 11 and/or the aperture body 3 are/is detachably mounted on the first part 18 of the housing body 2. As is apparent from FIG. 1, the two cooling bodies 10, 11 are mounted on the inner face 14. In contrast, the aperture body 3 is mounted on the outer face 15. Due to the multiple-part design of the housing body 2, the second cooling body 11, in particular, can be easily installed in and/or removed from the interior of the housing body 2. For the purpose of installing the first cooling body 10, the housing body 2 has an installation opening 27, via which the first cooling body 10 can be inserted into the housing interior 5.

During use as intended, the laser beam is therefore introduced via the aperture 4 into the housing interior 5, where the laser beam then strikes the rotatably mounted deflection element 8 of the first deflection unit 6 and, thereafter, the rotatably mounted deflection element 8 of the second deflection unit 7. In the end, the laser beam is guided out of the housing body 2 through an exit opening (not shown). It goes without saying that the scan system 1 can have even more optical components, which are subjected to heat input.

During operation of the scan system 1, heat input arises, in particular due to electrical losses of the drive 9 and of the at least one electronic component 16 and/or due to the absorption of the deflected laser beam in the region of the aperture 4 and of the at least one deflection element 8. This heat input must be dissipated from the scan system 1 via a coolant, in particular a liquid coolant, such as, for example, water. Temperature fluctuations and, in particular, temperature gradients must be kept low, so that the precision of the deflection units 6, 7 is not adversely affected by the thermal expansion and thermal deformation.

For this purpose, the scan system 1 according to FIG. 1 has a channel system 24 via which the coolant is conducted from an inlet 25 of the housing body 2 in the housing body 2 and/or through the housing body 2 to the components of the scan system 1 to be cooled. At the end of the channel system 24, the coolant is discharged from the housing body 2 via an outlet 26 of the housing body 2.

The channel system 24 includes at least one housing channel 28a-28i which is formed in the housing body 2, at least one cooling channel 29a, 29b, 30a, 30b which is formed in the first and/or the second cooling body 10, 11, and/or at least one cooling chamber 31, 32 which is formed in the housing body 2. The coolant can be distributed in the interior of the housing body 2 to the components to be cooled via the at least one housing channel 28a-28i. The coolant can be distributed inside the cooling body 10, 11 via the at least one cooling channel 29a, 29b, 30a, 30b and, as a result, the deflection unit 6, 7, which can be accommodated therein, is indirectly cooled. To this end, the at least one cooling channel 29a, 29b, 30a, 30b extends preferably symmetrically and/or adjacently to the receiving recess 12, 13, as is described in detail further below.

The at least one housing channel 28a-28i and/or the at least one cooling channel 29a, 29b, 30a, 30b include(s) at least one inlet channel opening 33 and at least one outlet channel opening 34. The coolant is introduced via the inlet channel opening 33 into the housing channel 28a-28i or cooling channel 29a, 29b, 30a, 30b. The coolant is discharged from the housing channel 28a-28i or the cooling channel 29a, 29b, 30a, 30b via the outlet channel opening 34.

The inlet channel opening 33 and/or the outlet channel opening 34 of the at least one housing channel 28a-28i are/is formed in the housing body 2 and/or one of its parts 18, 19. As a result, the at least one housing channel 28a-28i is completely integrated in the housing body 2 and/or one of its parts 18, 19. This means that the at least one housing channel 28a-28i is formed in and/or through the material of the housing body 2 and/or one of its parts 18, 19 and/or its inlet channel opening 33 and outlet channel opening 34 are located on a surface, in particular the contact surface 21, 22, 23, of the housing body 2 and/or one of its parts 22, 23. The housing channel 28a-28i is therefore delimited or defined over its entire length by the material of the housing body 2 and/or one of its parts 18, 19, except in the region of its at least one inlet channel opening 33 and outlet channel opening 34.

The inlet channel opening 33 and/or the outlet channel opening 34 of the at least one cooling channel 29a, 29b, 30a, 30b are/is formed in the cooling body 10, 11. Furthermore, the at least one cooling channel 29a, 29b, 30a, 30b is completely integrated in the cooling body 10, 11. This means that the at least one cooling channel 29a, 29b, 30a, 30b is formed in and/or through the material of the cooling body 10, 11 and/or its inlet channel opening 33 and output channel opening 34 are/is located on a surface, in particular the contact surface 20, of the cooling body 10, 11. The cooling channel 29a, 29b, 30a, 30b is therefore delimited or defined over its entire length by the material of the cooling body 10, 11, except in the region of its at least one inlet channel opening 33 and outlet channel opening 34.

The coolant is transferred between the parts 18, 19 of the housing body 2, between the housing body 2 and the first cooling body 10 and/or between the housing body 2 and the second cooling body 11 directly, i.e., without tubes connected therebetween. To this end, the abutting bodies have corresponding contact surfaces 20, 21, 22, 23 in which the corresponding channel openings 33, 34 are formed. The corresponding channel openings 33, 34 overlap and/or are coaxial with one another in order to ensure a tight connection. Additionally, at least one sealing element 45 can be arranged between the contact surfaces 20, 21, 22, 23, wherein only one sealing element 45 is provided with a reference character in the figures for the sake of clarity. The sealing element 45 can be, for example, an O-ring. The sealing element 45 extends in the circumferential direction around the corresponding channel openings 33, 34. In order to prevent the sealing element 45 from slipping, it is advantageous when a groove is formed in at least one of the corresponding contact surfaces 20, 21, 22, 23 in which groove the sealing element 45 is accommodated.

In order to reduce the manufacturing costs of the scan system 1, the channel system 24 is formed in the housing body 2 and/or the at least one cooling body 10, 11 by a material-removing production method, in particular drilling and/or milling.

Therefore, the at least one housing channel 28a-28i and/or the at least one cooling channel 29, 30 are/is formed by at least one bore. The bore preferably has a diameter which is constant over the entire length.

The bore can be formed as a through-hole 35 such that the inlet channel opening 33 is formed at its one end and the outlet channel opening 34 is formed at its other end.

Alternatively, the bore of a housing channel 28a-28i and/or of a cooling channel 29, 30 can also be in the form of a blind bore 36. In this case, the at least one housing channel 28a-28i and/or the at least one cooling channel 29, 30 have/has at least two blind bores 36, which intersect. As a result, the opening of the one blind bore 36 forms the inlet channel opening 33 and the opening of the other blind bore 36 forms the outlet channel opening 34. The intersecting blind bores 36 can form an acute, right or obtuse angle with one another. Preferably, the two blind bores 36 intersect at a housing-internal end of at least one of the two blind bores 36.

In order to reduce the manufacturing costs, the at least one cooling chamber 31, 32 is manufactured via milling such that the cooling chamber 31, 32 is formed as a milled recess 37. In this case, the cooling chamber 31, 32 has a manufacturing opening 38, 39 on the outer face 15 or the inner face 14 of the housing body 2. The manufacturing opening 38, 39 is tightly closed with the component to be cooled, in particular with the aperture body 3 or the electronic-component heat sink 17.

As is apparent from FIG. 1, the second part 19 of the housing body 2 has a first housing channel 28a. The inlet channel opening 33 of this first housing channel 28a forms the inlet 25 of the housing body 2. The first housing channel 28a is in the form of a through-hole 35. The first part 18 of the housing body 2 includes a second housing channel 28b, which adjoins the first housing channel 28a in a flush manner. To this end, the outlet channel opening 34 of the first housing channel 28a and the inlet channel opening 33 of the second housing channel 28b overlap, the outlet channel opening 34 and the inlet channel opening 33 being formed in the corresponding contact surfaces 22, 23. The first and the second housing channels 28a, 28b therefore form a first channel section in which an inlet flow 40 is conducted through the housing body 2, in particular through the second part 19 and partially through the first part 18.

The second housing channel 28b is formed by multiple interconnected blind bores 36. As a result, the second housing channel 28b includes an inlet channel opening 33, which faces the second part 19, and multiple, in particular two, outlet channel openings 34a, 34b, which face the first cooling body 10. In the second housing channel 28b, the inlet flow 40 is therefore divided into multiple, in particular two, cooling flows 41, 42 and fed to the first cooling body 10.

As is apparent, in particular, from the detailed view of the scan system 1 shown in FIG. 2, the first cooling body 10 has two separate cooling channels 29a, 30a, as described above. The cooling channels 29a, 30a are formed on two opposite longitudinal sides of the first receiving recess 12. Preferably, the two separate cooling channels 29a, 30a are symmetrical and/or congruent in relation to one another. According to the present exemplary embodiment, the cooling channels 29a, 30a are formed by two blind bores 36a, 36b, respectively, which intersect in the region of their housing-internal ends. As a result, the cooling channels 29a, 30a are V-shaped and/or form an acute angle with one another.

The inlet channel opening 33a, 33b and the outlet channel opening 34a, 34b of the first and/or the second cooling channel 29a, 30a are formed in the same contact surface 20 of the first cooling body 10 and/or on the same cooling-body side 43.

Via the two cooling channels 29a, 30a, the two cooling flows 41, 42 are conducted through the first cooling body 10 separately from one another on different sides and/or symmetrically in relation to one another, in particular with respect to the first receiving recess 12.

Separate third housing channels 28c, 28d adjoin the outlet channel openings 34a, 34b of the cooling channels 29a, 30a of the first cooling body 10. The third housing channels 28c, 28d are formed in the housing body 2 by two blind bores 36 in each case. Via these third housing channels 28c, 28d, the two cooling flows 41, 42 are guided separately from one another to the second cooling body 11. The interface between the second cooling body 11 and the housing body 2 is formed similarly to the first cooling body 10 according to the preceding description. The second cooling body 11 is also preferably identical to the first cooling body 10.

According to FIG. 1, at least one fourth housing channel 28e, 28f adjoins the second cooling body 11, via which fourth housing channel 28e, 28f the coolant is conducted to the first cooling chamber 31. In the present case, the housing body 2 has two fourth housing channels 28e, 28f, which are separate from one another. Via the two fourth housing channels 28e, 28f, the two cooling flows 41, 42—once these have been conducted through the first and the second cooling body 10, 11—are therefore conducted separately to the first cooling chamber 31.

The second housing channel 28b, the two separate cooling channels 29a, 30a of the first cooling body 10, the two separate third housing channels 28c, 28d, the two separate cooling channels 29b, 30b of the second cooling body 11 and/or the separate fourth housing channels 28e, 28f form a second channel section in which the inlet flow 40 is divided into the cooling flows 41, 42 in which these divided cooling flows 41, 42 are fed separately to the first cooling body 10 and, thereafter, to the second cooling body 11 and/or in which these two cooling flows 41, 42 are fed to the first cooling chamber 31.

The two fourth housing channels 28e, 28f extend into the first cooling chamber 31. There, the two cooling flows 41, 42 are combined to form one common cooling flow 44. The first manufacturing opening 38 of the first cooling chamber 31 is tightly closed by the aperture body 3. As a result, the coolant is conducted past the aperture body 3, in particular in the circumferential direction around the aperture 4.

A fifth housing channel 28g extends away from the first cooling chamber 31. The fifth housing channel 28g is formed by two intersecting blind bores 36, which have not been provided with a reference character, for the sake of clarity.

This fifth housing channel 28g is adjoined by a sixth housing channel 28h, which is formed in the second part 19 of the housing body 2. Here as well, the contact surfaces 22, 23 of the two parts 18, 19 of the housing body 2 and their intercommunicating channel openings are designed to correspond with one another such that a tight interface is formed, via which the coolant can be transferred from the first part 18 into the second part 19.

According to FIG. 1, the sixth housing channel 28h, which is formed by two blind bores 36 or, alternatively, by one blind bore 36 and a milled slot, extends into the second cooling chamber 32. As mentioned above, this second cooling chamber 32 also includes a second manufacturing opening 39, which is tightly closed by the electronic-component heat sink 17. As a result, the common cooling flow 44 is also conducted past the electronic-component heat sink 17 in the second cooling chamber 32 such that the electronic component 16 is cooled.

A seventh housing channel 28i extends from the second cooling chamber 32 to the outlet 26. The inlet 25 and the outlet 26 are formed on the same outer face of the housing.

According to the preceding description, the first cooling chamber 31, the fifth housing channel 28g, the sixth housing channel 28h, the second cooling chamber 32 and/or the seventh housing channel 28i therefore form a third channel section. In this third channel section, the two cooling flows 41, 42 are combined and this common cooling flow 44 is conducted through the housing body 2, in particular through the first cooling chamber 31 for cooling the aperture 4 and/or through the second cooling chamber 32 for cooling the electronic component 16.

In order to reduce the manufacturing costs, it is advantageous when all housing channels 28 and cooling chambers 31, 32 of the housing body 2 and/or all cooling channels 29, 30 of the cooling bodies 10, 11 are manufactured, in particular exclusively, by material-removing production methods, in particular via drilling and/or milling.

The presently disclosed subject matter is not limited to the exemplary embodiments that have been shown and described. Modifications within the scope of the claims are also possible, as is any combination of the features, even if they are represented and described in different exemplary embodiments.

### LIST OF REFERENCE CHARACTERS

1 scan system
2 housing body
3 aperture body
4 aperture
5 housing interior
6 first deflection unit
7 second deflection unit
8 deflection element
9 drive
10 first cooling body
11 second cooling body
12 first receiving recess
13 second receiving recess
14 inner face of the housing body
15 outer face of the housing body
16 electronic component
17 electronic-component heat sink
18 first part
19 second part
20 contact surface of the cooling body
21 contact surface of the housing body
22 contact surface of the first part
23 contact surface of the second part
24 channel system
25 inlet
26 outlet
27 installation opening
28 housing channel
29 first cooling channel
30 second cooling channel
31 first cooling chamber
32 second cooling chamber
33 inlet channel opening
34 outlet channel opening
35 through-hole
36 blind bore
37 milled recess
38 first manufacturing opening
39 second manufacturing opening
40 inlet flow
41 first cooling flow
42 second cooling flow
43 cooling-body side
44 common cooling flow
45 sealing element

1-20. (canceled)

21. A scan system for guiding a laser beam, the scan system comprising:
a housing body defining a housing interior, the housing body including at least one housing channel configured to distribute a coolant, the at least one housing channel being formed in the housing body; and
at least one cooling body arranged in the housing interior and being detachably connected to the housing body, the at least one cooling body defining a receiving recess configured to receive a deflection unit, the at least one cooling body having at least one cooling channel connected to the at least one housing channel that is configured to cool the deflection unit, the at least one cooling channel being formed in the at least one cooling body;
wherein:
the at least one housing channel and the at least one cooling channel are each formed by at least one bore; and
the housing body and the at least one cooling body have corresponding contact surfaces across which the housing body and the at least one cooling body abut one another such that a channel opening of the at least one housing channel, which is formed in the contact surface of the housing body, and a channel opening of the at least one cooling channel, which is formed in the contact surface of the at least one cooling body, overlap one another.

22. The scan system of claim 21, wherein the housing body has a first part on which the at least one cooling body and/or an aperture body are/is detachably mounted, and a second part in which an electronic-component heat sink is detachably mounted.

23. The scan system of claim 22, wherein the first and second parts have corresponding contact surfaces with corresponding channel openings; and
wherein the first and second parts abut one another at their corresponding contact surfaces such that a channel opening of the at least one housing channel, which is formed in the contact surface of the first part, and a channel opening of the at least one housing channel, which is formed in the contact surface of the second part, overlap one another.

24. The scan system of claim 21, wherein a sealing element is positioned between the corresponding contact surfaces of the housing body and the at least one cooling body and surrounds the overlapped channel openings.

25. The scan system of claim 21, wherein the at least one housing channel and/or the at least one cooling channel each have exclusively at least one inlet channel opening for introducing the coolant and at least one outlet channel opening for discharging the coolant.

26. The scan system of claim 21, wherein the at least one housing channel and/or the at least one cooling channel are/is formed by at least one through-hole and/or at least one blind bore.

27. The scan system of claim 21, wherein the at least one housing channel and/or the at least one cooling channel are/is formed by at least two blind bores, the at least two blind bores being oblique with respect to one another and intersecting one another.

28. The scan system of claim 21, wherein an inlet channel opening and an outlet channel opening of the at least one cooling channel are formed on the at least one cooling body in the same contact surface of the at least one cooling body and/or on a same side of the at least one cooling body.

29. The scan system of claim 21, wherein an inlet channel opening and an outlet channel opening of the at least one cooling channel are formed on the housing body (28) in different contact surfaces and/or on different sides of the housing body.

30. The scan system of claim 21, wherein the at least one cooling body has a first cooling channel and a separate second cooling channel.

31. The scan system of claim 30, wherein the first and second cooling channels are identical to one another and/or are arranged in parallel and/or symmetrically to one another.

32. The scan system of claim 30, wherein a common plane of symmetry of the first and second cooling channels extends centrally through the receiving recess.

33. The scan system of claim 21, wherein the housing body has at least one cooling chamber configured to cool an electronic component and/or an aperture formed at least partially in the housing body.

34. The scan system of claim 33, wherein the at least one cooling chamber is die cut into the housing body and/or has a manufacturing opening on one of an inner face facing the housing interior or on an outer face facing away from the housing interior.

35. The scan system of claim 33, wherein the at least one cooling chamber comprises a first cooling chamber configured to cool the aperture, the first cooling chamber having a first manufacturing opening that is on an outer face of the housing and is tightly closed by an aperture body detachably connected to the housing.

36. The scan system of claim 35, wherein the at least one cooling chamber further comprises a second cooling chamber configured to cool the electronic component, the second cooling chamber having a second manufacturing opening that is on an inner face of the housing body and is tightly closed by an electronic-component heat sink detachably connected to the housing body.

37. The scan system of claim 21, wherein the housing body has an inlet and an outlet for the coolant, the inlet and outlet being arranged on a same side of the housing body.

38. The scan system of claim 37, wherein the scan system has a channel system extending from the inlet to the outlet and being at least partially formed by the at least one housing channel and the at least one cooling channel.

39. The scan system of claim 38, wherein the channel system has, in a direction of flow, a first channel section that conducts an inlet flow of the coolant from the inlet through the housing body and a second channel section that divides the inlet flow into two cooling flows and conducts the two cooling flows, separate from one another and/or connected in parallel, through the housing body and/or the at least one cooling body of the at least one deflection unit, and a third channel section that combines the two cooling flows to form a common cooling flow and conducts the common cooling flow through the housing body to the outlet.

40. A housing body or cooling body designed for use in the scan system of claim 21.
